(19) United States
(12) Patent Application Publication
(10) Pub. No.: US 2026/0304711 A1
(43) Pub. Date: Oct. 1, 2026

(54) SYSTEM AND METHOD FOR COMPRESSION MECHANISM FOR COOLING LOOP TO A DATA PROCESSING SYSTEM

(71) Applicant: Dell Products L.P., Round Rock, TX (US)

(72) Inventors: MEGAN CHERIE WINGFIELD, Dalzell, SC (US); JAMES R. UTZ, Georgetown, TX (US)

(21) Appl. No.: 19/094,600

(22) Filed: Mar. 28, 2025

(51) Int. Cl. H05K 7/20

(52) U.S. Cl. CPC H05K 7/208; H05K 7/20327; H05K 7/20354; H05K 7/2049

(57) ABSTRACT

Methods, systems, and devices are provided for managing a system that may include rack for housing data processing systems. The data processing systems may include a heat generating component, a chassis for housing the heat generating component, a liquid cooling loop to cool the heat generating component, and a compression mechanism. The compression mechanism may be adapted to reversibly seal a portion of the liquid cooling loop to prevent coolant from being circulated by the liquid cooling loop into an interior of the data processing system. The portion of the liquid cooling loop may be positioned upstream of the heat generating component and positioned outside of the chassis. By utilizing the compression mechanism, forces may be applied to the liquid cooling loop to reversibly seal the fluid flow through the liquid cooling loop to a respective data processing system without impacting fluid flow to other data processing systems.

### FIELD

Embodiments disclosed herein relate generally to management of data processing systems. More particularly, embodiments disclosed herein relate to systems and methods for mitigating damage to data processing systems.

### BACKGROUND

Computing devices may provide computer implemented services. The computer implemented services may be used by users of the computing devices and/or devices operably connected to the computing devices. The computer implemented services may be performed with hardware components such as processors, memory modules, storage devices, and communication devices. The operation of these components may impact the performance of the computer-implemented services.

### BRIEF DESCRIPTION OF THE DRAWINGS

Embodiments disclosed herein are illustrated by way of example and not limitation in the figures of the accompanying drawings in which like references indicate similar elements.

FIG. 1 shows a block diagram illustrating a system in accordance with an embodiment.

FIG. 2A shows a diagram illustrating fluid management mechanisms for a rack system in accordance with an embodiment.

FIGS. 2B-2E show diagrams illustrating a compression mechanism in accordance with an embodiment.

FIGS. 2F-2G show diagrams illustrating a compression mechanism in accordance with an embodiment.

FIG. 3 shows a block diagram illustrating a data processing system in accordance with an embodiment.

### DETAILED DESCRIPTION

Various embodiments will be described with reference to details discussed below, and the accompanying drawings will illustrate the various embodiments. The following description and drawings are illustrative and are not to be construed as limiting. Numerous specific details are described to provide a thorough understanding of various embodiments. However, in certain instances, well-known or conventional details are not described in order to provide a concise discussion of embodiments disclosed herein.

Reference in the specification to “one embodiment” or “an embodiment” means that a particular feature, structure, or characteristic described in conjunction with the embodiment can be included in at least one embodiment. The appearances of the phrases “in one embodiment” and “an embodiment” in various places in the specification do not necessarily all refer to the same embodiment.

References to an “operable connection” or “operably connected” means that a particular device is able to communicate with one or more other devices. The devices themselves may be directly connected to one another or may be indirectly connected to one another through any number of intermediary devices, such as in a network topology.

In general. embodiment disclosed herein relate to methods and systems for managing data processing systems that may provide, at least in part, computer implemented services. The computer-implemented services may be provided to any type and/or number of other devices and/or users of the data processing systems. Furthermore, the provided computer implemented services may be of any quantity and/or type of such services.

To provide the computer implemented services, the data processing systems may include hardware components. For example, operation of these hardware components may facilitate various functionalities of a data processing system of the data processing systems, thereby causing the data processing system to provide the computer implemented services.

However, the operation of said hardware components may generate heat, for example, due to electrical energy (e.g., the electricity flow through wires, transistors and other components) converting into heat. To regulate this heat, a liquid cooling system may be used with the data processing system to circulate a cooling liquid adapted to dissipate at least a portion of the heat generated by the hardware components.

However, by circulating the cooling liquid (and/or otherwise having liquid within the system), a likelihood of liquid damage and/or other complications associated with using (e.g., integrating) the liquid cooling system negatively impacting the hardware components may be increased.

For example, the liquid cooling system may rely on a manifold (positioned with a rack that houses the data processing systems) to provide and/or receive the cooling liquid, connection points between the manifold and the liquid cooling system may become vulnerable. For example, the vulnerabilities may be induced by an increased likelihood of debris (and/or otherwise detrimental foreign matter) obstructing any of the connection points, entering the manifold (e.g., and polluting the cooling liquid), and/or damaging the connection points and/or other portions of the liquid cooling system. These vulnerabilities may therefore result in, for example, leaks occurring in the liquid cooling system and/or a deprecation of heat dissipation, such results thereby risking damage (directly and/or indirectly) to any of the hardware components of the data processing system via, for example, liquid damage and/or heat damage.

A current solution to solving the issues may include using quick-connect and quick-disconnect fittings, which allow for fluid lines to be disconnected without major leaks. However, the quick connections and quick-disconnections are mechanically complex and may require precise actuation mechanisms (e.g., specialized actuators) to operate effectively. Due to the complexity of the quick-connect and quick-disconnect fittings, the cost may not be feasible for widespread deployment across many data processing systems and/or rack systems including housing multiple data processing systems.

Consequently, complications resulting from such vulnerabilities may negatively impact the operation of the hardware components. These negative impacts on the operation of the hardware components may, in turn, negatively impact the computer implemented services by also impacting the data processing systems negatively. For example, such negative impacts may include delaying the computer implemented services to be provided by the data processing systems based on the operation, and/or preventing the computer implemented services from being provided entirely.

To decrease the likelihood of such negative impacts, at least one compression mechanism may be used to reversibly seal a portion of the liquid cooling loop (e.g., of the liquid cooling system) to prevent coolant from being circulated by the liquid cooling loop into an interior of the data processing system. The portion of the liquid cooling loop may be sealed by deforming a portion of the liquid cooling loop to seal a fluid flow path through the liquid cooling loop (e.g., which cooling liquid flows for dissipating heat generated by components housed within the chassis).

Therefore, the at least one compression mechanism may, for example, be used with a rack system in which (i) one or more of the chassis are mounted in a rack, (ii) the manifold is positioned with the rack, and (iii) fluid communication between the one or more of the chassis and the manifold may be facilitated and/or reversibly sealed by the compression mechanism by application of pressure to at least two external sides of the portion of the liquid cooling loop.

For example, the manifold may be adapted to provide the cooling fluid to each of the chassis mounted in the rack while in fluid communication with each of the chassis. Based on conditions presenting affecting a data processing system, a signal may be provided to an actuator coupled to a compression mechanism to automatically shut off (e.g., prevent) the flow of coolant through the liquid cooling loop to the data processing system. For example, when a leak is detected or in a circumstance when a data processing unit is turned off (e.g., the data processing system is powered down and not generating heat), coolant may be restricted from flowing through the liquid cooling loop to the respective data processing system.

By doing so, a reliable, reversible method to control coolant flow to individual data processing units may be increased, thereby reducing the likelihood of unnecessarily circulation of coolant to individual data processing systems, eliminating the need for expensive, complex quick connection and quick disconnect fittings, and providing an automatic responsive to conditions impacting individual data processing systems to reduce unnecessary cooling operations (e.g., increasing energy efficiency).

In an embodiment, a data processing system is provided. The data processing system may include a heat generating component; a liquid cooling loop to cool the heat generating component; and a compression mechanism adapted to: reversibly seal a portion of the cooling loop to prevent coolant from being circulated by the liquid cooling loop into an interior of the data processing system, the portion of the cooling loop being sealed by deforming a portion of the liquid cooling loop to seal a fluid flow path through the liquid cooling loop.

The portion of the liquid cooling loop may be deformed through application of pressure to at least two external sides of the portion of the liquid cooling loop.

The portion of the liquid cooling loop may include a deformable tube, and the application of the pressure to at least two external sides causes a cross section to change from being circular in shape to elliptical in shape.

The compression mechanism may include: an actuatable return mechanism adapted to press a surface of the compression mechanism against the portion of the cooling loop to cause the deforming of the portion of the liquid cooling loop.

The actuatable return mechanism may be a return spring.

The actuatable return mechanism may be a powered scissor mechanism.

The compression mechanism may also include: an actuator coupled to the actuatable return mechanism, the actuator being coupled to a control system, and the control system being adapted to actuate the actuator based on conditions present in the data processing system.

The data processing system may also include: a chassis for housing the heat generating component, wherein the portion of the cooling loop may be positioned outside of the chassis.

The liquid cooling loop may be at least partially positioned inside of the chassis and at least partially positioned outside of the chassis.

The portion of the liquid cooling loop may be positioned upstream of the heat generating component.

In an embodiment, a rack system is provided. The rack system may including a rack for housing data processing systems; and a data processing system positioned in the rack, the data processing system may include: a heat generating component; a liquid cooling loop to cool the heat generating component; and a compression mechanism adapted to: reversibly seal a portion of the cooling loop to prevent coolant from being circulated by the liquid cooling loop into an interior of the data processing system, the portion of the cooling loop being sealed by deforming a portion of the liquid cooling loop to seal a fluid flow path through the liquid cooling loop.

In an embodiment, an enclosure for a data processing system is provided. the enclosure may include a liquid cooling loop to cool a heat generating component positioned in the enclosure; and a compression mechanism adapted to: reversibly seal a portion of the cooling loop to prevent coolant from being circulated by the liquid cooling loop into an interior of the data processing system, the portion of the cooling loop being sealed by deforming a portion of the liquid cooling loop to seal a fluid flow through the liquid cooling loop.

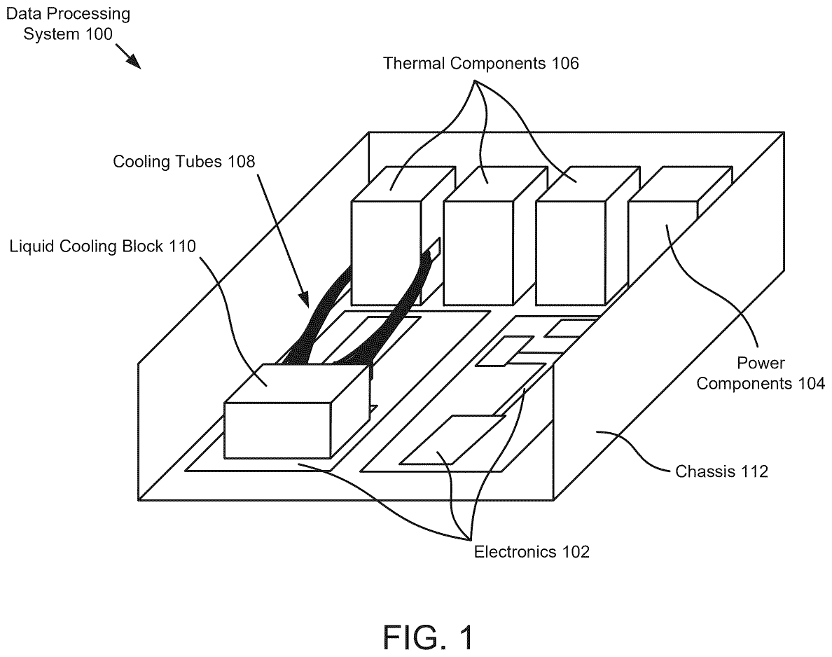

Turning to FIG. 1, a block diagram illustrating a data processing system (e.g., 100) in accordance with an embodiment is shown. The data processing system shown in FIG. 1 may be included in a rack system (e.g., 200, discussed further below) and may provide computer implemented services.

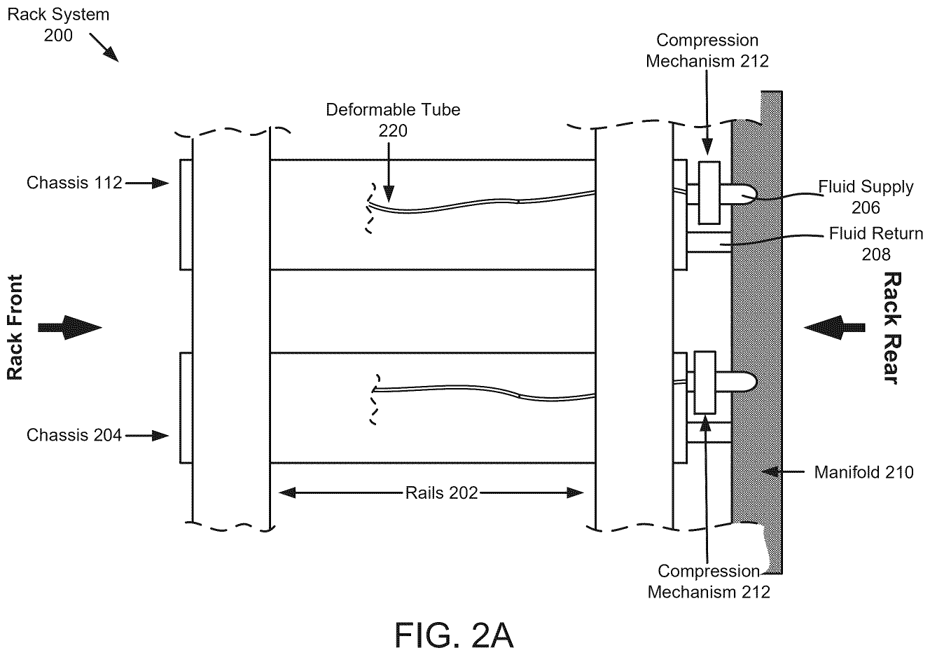

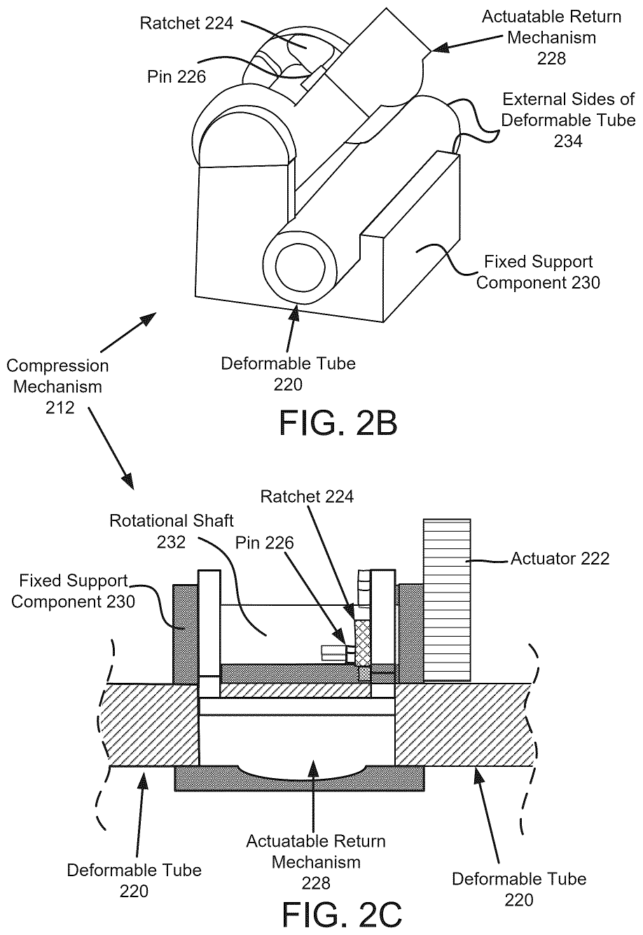

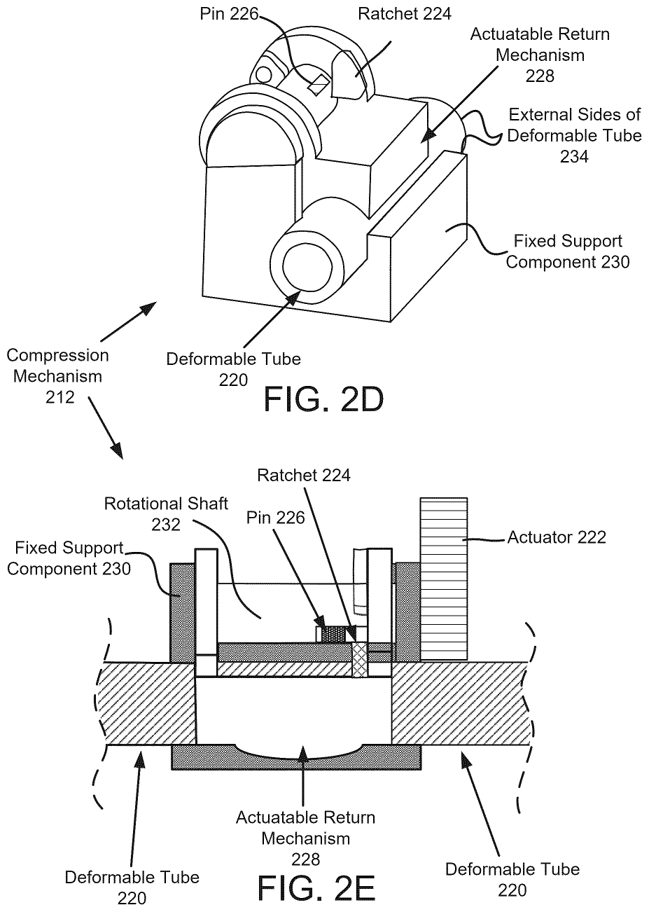

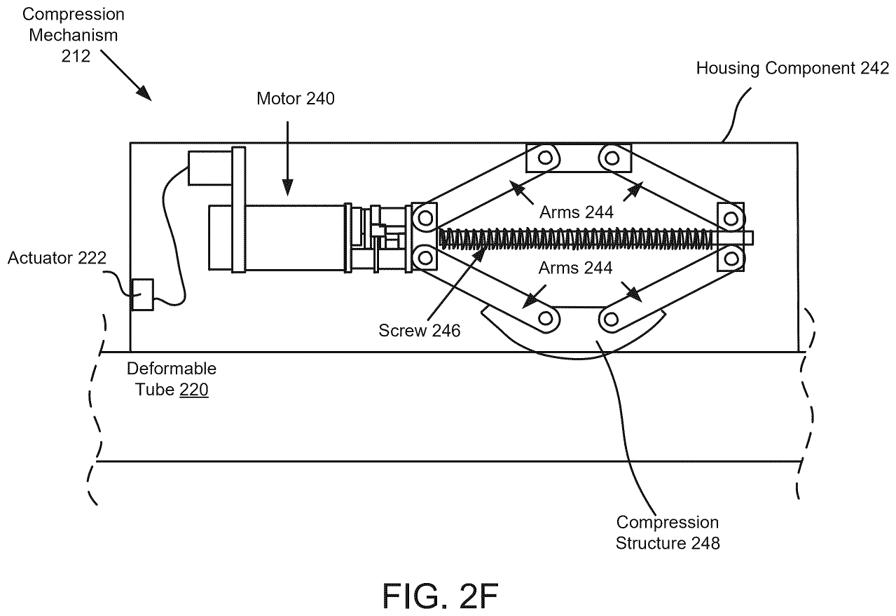

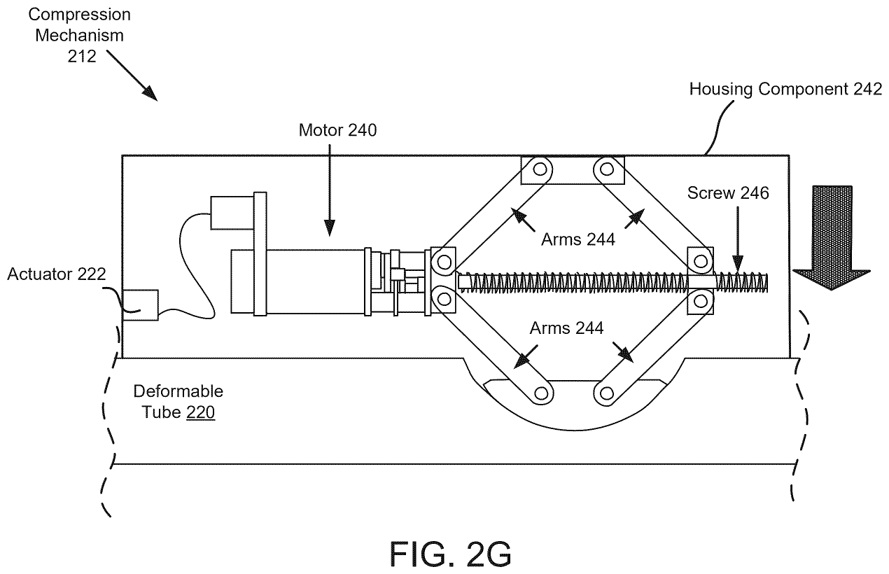

The computer implemented services may include any type and quantity of computer implemented services. The computer implemented services may include, for example, database services, data processing services, electronic communication services, and/or any other services that may be provided using one or more computing devices. The computer implemented services may be provided by, for example, any portion of data processing system 100, and/or any other type of devices positioned with a rack mount chassis system (e.g., 200) in which data processing system 100 may be placed (e.g., as shown in FIG. 2A).

Other types of computer-implemented services may be provided by the system shown in FIG. 1 without departing from embodiments disclosed herein.

To provide the computer implemented services, data processing systems may include any number of hardware components. For example, operation of the any number of hardware components may facilitate various functionalities of a data processing system, thereby causing the data processing system to provide the computer implemented services. For example, to facilitate the various functionalities, a hardware component may transmit data to and/or from other devices via various avenues of communication. For example, such avenues of communication may depend on physical operable connections that directly connect multiple hardware components to one another.

To provide the above noted functionality, the system of FIG. 1 may include data processing system 100. Data processing system 100 may include electronics 102, chassis 112, power components 104, and thermal components 106. Each of these is discussed below.

Electronics 102 may include at least a portion of the any number of hardware components, and as noted above, may provide computer implemented services. Hardware components of electronics 102 may be positioned on circuit cards and may generate heat while operating. Circuit cards may be pieces of circuit boards, for example.

Electronics 102 and/or any other components of the any number of hardware components of data processing system 100 may be positioned in chassis 112. Chassis 112 may include an enclosure in which physical structures of electronics 102 (e.g., processors, memory, etc.), and/or other components of data processing system 100 may be positioned. For example, chassis 112 may facilitate placement and management of electronics 102 and/or other components (e.g., power components 104 and/or thermal components 106) in computing environments such as those discussed herein.

Power components 104 may power the any number of hardware components of data processing system 100. In some cases, for example, power components 104 may be implemented using power supplies. In other cases, for example, power components may be implemented using power rails and/or other types of operable connections that receive/distribute power provided by a busbar that distributes power throughout a rack system (e.g., 200 in FIG. 2A), the power being provided to the busbar by power supplies, for example.

Furthermore, operation of these power supplies and any other power components may also contribute to the generation of heat. If left unregulated, this generation of heat may increase a likelihood of negatively impacting the components.

To manage the heat, data processing system 100 may include thermal components 106. Thermal components 106 (otherwise referred herein as “heat generating components”) may thermally manage any of the components of data processing system 100. For example, thermal components 106 may include components such as cooling fans, coolant reservoirs, receiving elements for coolant, coolant (e.g., the cooling liquid), circulation pumps, manifolds or other types of flow control components, and/or other components to facilitate performance of liquid-based cooling of at least some of electronics 102. For example, thermal components 106 may be used with cooling tubes 108 and liquid cooling block 110, each of which is discussed below.

Liquid cooling block 110 may facilitate a dissipation of heat generated by, for example, electronics 102 by circulating the cooling fluid via cooling tubes 108. To provide its functionality, liquid cooling block 110 operate as a heat sink for some electronic components. For example, liquid cooling block 110 may be placed with an electronic component to (i) receive heat generated by the electronic components, and (ii) dissipate the received heat into the cooling liquid circulated through liquid cooling block 110. While providing its functionality, a transference of at least a portion of the generated heat may be facilitated.

For example, the cooling liquid, confined to a flow path that circulates through a loop of a liquid cooling system (e.g., cooling tubes 108, liquid cooling block 110, external components such as large scale coolant chillers, flow controllers, etc.), may be placed in thermal communication with a hardware component of electronics 102 that is and/or has been generating heat when the cooling liquid is flowing through a portion of the loop that is proximate to the hardware component. By being in this thermal communication, the cooling liquid may be heated while the heat generated by the hardware component is dissipated into the cooling liquid, thereby regulated the temperature of the hardware component.

Due to the cooling liquid circulating through liquid cooling block 110, this heated cooling liquid may flow to another portion of the loop (e.g., external to data processing system 100 such as a large-scale chiller). Thus, the cooling liquid may be cyclically heated and cooled as the cooling liquid continues to flow through the loop, thereby contributing to the dissipation of heat generated by the any number of hardware components of electronics 102.

For example, the cooling liquid may be directed through an interior of liquid cooling block 110 and through a first portion of cooling tubes 108. Cooling tubes 108 may further facilitate the circulation by directing the cooling liquid, for example, to other cooling blocks proximate to other hardware components of electronics 102 to facilitate cooling of multiple hardware components of electronics 102. To do so, cooling tubes 108 may include hollow, tubular structures in which liquid may flow through. For example, the cooling liquid, once cooled by external chillers, may then be further circulated through a second portion of cooling tubes 108 to direct the cooling liquid back through the liquid cooling block 110 to facilitate transference of additional heat generated by electronics 102.

However, by circulating the cooling liquid (and/or otherwise having liquid within the system), a likelihood of negatively impacting operation of the hardware components may be increased. For example, to provide its functionality, the liquid cooling system may rely on an established fluid connection between a quick disconnect socket of a manifold positioned with a rack, and a liquid cooling port of a chassis that houses at least some of the hardware components mounted on the rack, cooling liquid being adapted to flow into the chassis from the manifold via the established fluid connection.

However, a number of circumstances may require such fluid connections to be severed and/or prevented to preserve an integrity of the liquid cooling system (e.g., to prevent leaks), for example, during circumstances in which the system is subject to unpredictable movements and/or conditions. Such circumstances may include, for example, manufacture of the system, deployment of the system, maintenance of the system, etc.

During such circumstances, the system may, for example, be vulnerable to leaks in the cooling liquid housed within the manifold, thereby leaving passage through the liquid cooling loops and therein making the physical components of the data processing system vulnerable to damage.

Such a vulnerability may be due to an increased likelihood of the debris (and/or any other otherwise detrimental foreign matter) (i) obstructing any portion of the passage, (ii) entering the manifold (e.g., and polluting the cooling liquid), and/or (iii) infiltrating any number of portions of the liquid cooling system, thereby risking damage to any and all components included in the system.

A current solution to solving the issues may include using quick-connect and quick-disconnect fittings, which allow for fluid lines to be disconnected without major leaks. However, the quick connections and quick-disconnections are mechanically complex and may require precise actuation mechanisms (e.g., specialized actuators) to operate effectively. Due to the complexity of the quick-connect and quick-disconnect fittings, the cost may not be feasible for widespread deployment across many data processing systems and/or rack systems including housing multiple data processing systems.

Such vulnerabilities may therefore result in, for example, leaks occurring in the liquid cooling system and/or functionality of the liquid cooling system to be otherwise deprecated, such results thereby risking damage (directly and/or indirectly) to any of the hardware components of the data processing systems (e.g., components being subject to liquid damage and/or heat damage from heat that is prevented from dissipating correctly and/or efficiently).

Consequently, complications resulting from such vulnerabilities may negatively impact the operation of the hardware components. These negative impacts on the operation of the hardware components may, in turn, negatively impact the computer implemented services. For example, such negative impacts may include delaying the computer implemented services to be provided by the data processing systems based on the operation, and/or preventing the computer implemented services from being provided entirely.

To decrease the likelihood of such negative impacts, at least one compression mechanism may be used to manage, at least in part, a portion of a liquid cooling loop of the system. For example, management of the liquid cooling loop may include managing, at least in part, the fluid flow through the portion of the liquid cooling loop between a chassis of the data processing system and the manifold (e.g., from which the liquid coolant flows for dissipating heat generated by heat generating components housed within the chassis).

Therefore, the at least one compression mechanism may, for example, be used with a rack system in which (i) one or more of the chassis are mounted in a rack, (ii) the manifold is positioned with the rack, and (iii) fluid connections between the one or more chassis and the manifold may be facilitated and/or reversibly sealed by adaptation of the compression mechanism. The compression mechanism may therefore (i) isolate the coolant flow to individual data processing systems without affecting fluid flow to other data processing systems in the rack system (e.g., one or more chassis mounted in the rack), (ii) intentionally preventing fluid flow through the portion of the liquid cooling loop at a point in time (e.g., based on conditions present in the respective data processing system), (iii) be removed from sealing the fluid flow through the liquid cooling loop (e.g., when the fluid flow is to be established and/or resume), (iv) eliminate the need for expensive, elaborate quick disconnects, and (iv) allow for application post deployment across many systems.

Thus, as previous discussed, the manifold may be adapted to provide the cooling liquid to each of the chassis mounted in the rack while in fluid communication with each of the chassis (e.g., via the fluid connection). This fluid communication may be facilitated, at least in part, by one of the liquid cooling loops directing the fluid flow from the manifold to the heat generating components housed in the chassis. Alternatively, a compression mechanism positioned upstream of the heat generating component and positioned to seal a portion of the liquid cooling loop, at least partially, positioned outside of the chassis, the compression mechanism having a decreased likelihood of enabling the previously discussed vulnerability. Therefore, such as rack system may have an increased likelihood of providing the computer implemented services as expected and/or desired by consumers of such services.

While illustrated in FIG. 1 with a limited number of specific components, a system may include additional, fewer, and/or different components without departing from embodiments disclosed herein.

While illustrated in FIG. 1 as included a limited number of specific components, a system in accordance with an embodiment may include fewer, additional, and/or different components than those illustrated therein.

To further clarify embodiments disclosed herein, diagrams illustrating examples of a rack system (and/or portions thereof) in accordance with embodiments are shown and discussed with regard to FIG. 2A. Furthermore, diagrams illustrating examples of a compression mechanism in accordance with embodiments are shown and discussed further below with regarding to FIGS. 2B-2G.

Turning to FIG. 2A, a diagram illustrating a side view of a rack system (e.g., 200, an example of the previously mentioned rack system) in accordance with an embodiment is shown (e.g., a front side and rear side of rack system 200 being depicted on a left-hand side and on a right-hand side, respectively, of the page).

Rack system 200 may be used to position and/or otherwise manage any number of chassis (e.g., of any number of data processing systems) with regard to one another. To do so, rack system 200 may include rails 202 (e.g., as part of a rack of the rack system) to fixedly secure (e.g., mount) each chassis to a respective height between the rails. For example, a second chassis (e.g., 204) may be positioned just under data processing system 100, separated by a distance along the length of rails 202.

Additionally, for any of these any number of chassis to be in respective operable positions for facilitating functionality of rack system 200, each chassis may, for example, be pushed and/or otherwise positioned as far back in the rack (towards a rear of the rack) as possible. Therefore, when pulled and/or otherwise moved towards a front of the rack (e.g., to view a respective chassis interior and/or remove the chassis from the rack), a respective chassis may not be in a respective operable position and may therefore be unable to provide computer implemented services. This dependance on being positioned in a respective operable position to provide the computer implemented services may be due to, for example, a use (e.g., a presence) of quick connections 206 within rack system 200.

It will be appreciated that although chassis 204 is not used in all the examples regarding chassis 112, chassis 204 (as well as any other chassis of the any number of data processing systems positioned in the rack) may facilitate and/or be included in, but not limited to, any number of processes/operations discussed herein with regard to chassis 112.

For example, and as previously discussed, rack system 200 may include a manifold such as manifold 210. This manifold 210 may provide and/or receive cooling liquid intended, at least in part, for thermal management of chassis 112 (and therefore, data processing system 100). Therefore, to provide chassis 112 with the cooling liquid, fluid communication may, for example, be required (and thus, established) between each of the mounted chassis and manifold 210.

To provide its functionality, manifold 210 may be implemented with a hollow, enclosed (e.g., metal) tube that may, for example, (i) be positioned at the rack rear, (ii) span a height of the rack, and (iii) be adapted to distribute the cooling liquid throughout rack system 200, the distribution engaging each mounted chassis from along the spanned height of the rack.

To establish the fluid communication between, for example, chassis 112 and manifold 210, the system of FIG. 2A may include compression mechanism 212 (further discussed below with regard to FIG. 2B) adapted to reversibly seal fluid flow path between respective distribution points of/along manifold 210 and the liquid cooling system at least partially housed by chassis 112. Although illustrated in FIG. 2A as the compression mechanism 212 being positioned outside of the chassis 112 and coupled to deformable tube 220, it may be understood that compression mechanism 212 may be positioned at any portion of deformable tube 220 (and/or any type of deformable tube) that may allow for reversible sealing of fluid flow (e.g., coolant for heat generating components) to a respective data processing system. For example, compression mechanism 212 may be positioned within chassis 112 so that it may seal a portion of the deformable tube positioned inside of the chassis thereby restricting the flow of coolant inside the chassis.

The liquid cooling system may include a liquid cooling loop for each respective data processing system hosted by the rack system and a portion of the liquid cooling loop at least being positioned outside the respective chassis. For additional information regarding compression mechanism 212 and/or managing the fluid communication, refer to FIGS. 2B-2G, below.

Turning to FIGS. 2B-2C, a diagram illustrating an isometric view and diagram illustrating a front-side point of view (e.g., respectively) of a compression mechanism 212 coupled to a portion of a deformable tube 220 in accordance with an embodiment is shown (e.g., the compression mechanism (i) being proximate to manifold 210 and (ii) before the thermal components 106).

As previously discussed, manifold 210 may provide the cooling liquid to various chassis and/or may allow the cooling liquid to leave these chassis. To do so, fluid communication between chassis 112 and manifold 210 may be managed (e.g., established and maintained and/or severed and prevented).

To manage this fluid communication, various components (such as compression mechanism 212 mentioned previously with regard to FIG. 2B) associated with liquid cooling systems may be used (e.g., integrated) with rack system 200. For example, any of compression mechanism may enable chassis 112 to be positioned with the rack of rack system 200 such that a chassis port (not explicitly shown in FIG. 2B) of chassis 112 is secured (e.g., sealed) to a port of the manifold (e.g., compression mechanism 212 coupled to deformable tube 220) that allows for the cooling liquid to flow through manifold into chassis 112.

As previously described above in FIG. 2A, compression mechanism 212 may be (i) positioned outside of the chassis (e.g., chassis 112), and (ii) coupled to a portion of the liquid cooling loop (e.g., deformable tube 220), where the portion of the liquid cooling loop may be upstream of the thermal components 106 of data processing system 100.

Compression mechanism 212 may include fixed support component 230, an actuatable return mechanism 228, and an actuator 222 (e.g., shown in FIG. 2C) coupled to actuatable return mechanism 228.

Fixed support component 230 may include a static component fixed to a portion of rack system 200 and positioned outside the chassis of respective data processing systems. Fixed support component 230 may provide structural support for components of compression mechanism 212 (e.g.,, including actuatable return mechanism 228, rotational shaft 232, actuator 222, etc.) and a portion of deformable tube 220 (e.g., a portion of the liquid cooling loop as shown in FIG. 2B).

As shown in FIG. 2B, an initial state (e.g., an open position) of actuatable return mechanism 228 is illustrated. In order to place actuatable return mechanism 228 is the initial state, a ratchet 224 (e.g., a toothed or angled surface) may be attached to actuatable return mechanism 228 and may be designed to engage with pin 226 to maintain the position of the pin (e.g., lock pin 226 into place). The shape of ratchet 224 may allow pin 226 to hold actuatable return mechanism 228 in an open position but may allow disengagement when required. For example, pin 226 may be positioned along rotational shaft 232 (e.g., explicitly shown in FIG. 2C) such that it sits in a notch or groove of ratchet 224 (e.g., when actuatable return mechanism 228 is in the open position), thereby preventing actuatable return mechanism 228 from moving (e.g., due to external forces).

For example, a torsion spring (e.g., not explicitly shown in FIGS. 2B-2C) may be coupled to actuatable return mechanism 228 such that rotation of the actuatable return mechanism into an open position (e.g., counter-clockwise direction as shown in FIG. 2B) may cause compression of the spring (e.g., storage of mechanical energy in the form of potential energy, ready to be released as rotational force or torque). The torsion spring may store sufficient energy to rotate actuatable return mechanism 228 into a closed position (e.g., shown in FIGS. 2D-2E) but may be restrained by the force applied by pin 226 against ratchet 224.

Consequently, to reverse the seal of the fluid flow through the deformable tube 220 (e.g., remove the force applied to deformable tube 220), physical intervention (e.g., by a human) may be necessary to reset the actuatable return mechanism 228 and reset the actuatable return mechanism 228 to an open position (e.g., as shown in FIG. 2B).

Turning to FIG. 2D, a diagram illustrating the same isometric view as shown in FIG. 2B and FIG. 2E, a diagram illustrating the same front-side point of view as shown in FIG. 2C, in accordance with an embodiment is shown.

Assume that the diagrams illustrated in FIGS. 2B-2C is a first instance of the previously discussed compression mechanism 212 that occurs moments before actuatable return mechanism 228 is rotated down all the way on deformable tube 220 (e.g., rotated clockwise onto deformable tube 220).

Further assume that the diagrams illustrated in FIGS. 2D-2E is a second instance of the previously discussed compression mechanism that occurs after pin 226 is pushed away from the ratchet 224 (e.g., pushed to the left towards the opposite end of the rotational shaft 232 as shown in FIG. 2E).

As shown in FIG. 2D, and in contrast to the discussion of FIG. 2B, the pushing of pin 226 in a horizontal motion away from ratchet 224 allows the pressure of a spring (e.g., positioned along rotational shaft 232 but not explicitly shown in FIGS. 2B-2E) to cause actuatable return mechanism to press down on a portion of the deformable tube 220 in order to seal a fluid flow path through the deformable tube 220. When disallowing the fluid communication, this enacted pressure may facilitate various adaptations (e.g., deformations) of the external sides of the portion of the liquid cooling loop (e.g., external sides of deformable tube 220) that cause the fluid flow path through deformable tube 220 to be sealed.

Deformable tube 220 may be subjected to an external force (e.g., caused by actuatable return mechanism 228 as shown in FIGS. 2D-2E) and as such, deformable tube 220 may deform to occlude the flow of the liquid coolant to flow through deformable tube 220. For example, as deformable tube 220 is pinched (e.g., application of pressure to at least two external sides of deformable tube 220), a cross sectional area of the liquid cooling loop may be decreased. For example, due to the application of pressure to the at least two external sides of the deformable tube 234 by the actuatable return mechanism 228, a cross section of deformable tube 220 may change from a circular shape to an elliptical shape.

Application of actuatable return mechanism 228 may be initiated by an actuator 222. Actuator 222 may be any type of powered actuator capable of receiving a signal (e.g., from a control center, external device, etc.) to actuate pin 226 to place it in a position to allow ratchet 224 to move thereby actuating actuatable return mechanism 228 (e.g., conversion of potential energy into kinetic energy of the spring coupled to the rotational shaft 232) to apply downward pressure on deformable tube 220. For example, the force from actuator 222 may move pin 226 out of engagement with ratchet 224, thereby clearing the path for actuatable return mechanism 228 to move. Consequently, as pin 226 is displaced, ratchet 224 may not be constrained, and the stored energy in the spring is released.

Actuator 222 may be coupled to a control system (e.g., not explicitly shown in FIGS. 2B-2E) adapted to actuate actuator 222 based on conditions present in the data processing system. For example, actuator 222 may receive a signal to seal the fluid flow path through the deformable tube 220 to a data processing system (e.g., 100) based on various factors. For example, a data center may include a management system that receives telemetry data from various data processing systems, such as operating state, leak detection, etc. The management system may identify a leak in one of the liquid cooling loops (e.g., providing cooling liquid to data processing system 100) that could damage (directly and/or indirectly) components of the data processing system based on the telemetry data.

To prevent such physical damage (e.g., by leaks in the liquid cooling system) to data processing system 100 (e.g., while maintaining fluid flow path to other data processing systems in a liquid cooling system), the management system may send a signal to actuator 222 to seal the flow of fluid through the portion of the liquid cooling loop supplying the cooling liquid to data processing system 100.

When actuator 222 is triggered (e.g., via a signal received from an control system), force applied by actuator 222 may cause pin 226 to move in a position such that pin 226 is out of engagement with ratchet 224, thereby allowing path for actuatable return mechanism 228 to move in a clockwise position (e.g., downward upon deformable tube 220). The stored energy in the torsion spring may be released as soon as pin 226 is displaced and the ratchet is no longer constrained.

For example, with pin 226 disengaged, the torsion spring may rapidly rotate actuatable return mechanism 228 shut, thereby applying downward pressure on deformable tube 220 causing the deformation of the portion of the liquid cooling loop. By doing so, the flow of fluid throughout the liquid cooling loop for data processing system 100 may be restricted. Consequently, a likelihood of managing potential physical damage to hardware components (e.g., caused by leaks in the liquid cooling loop) may be increased and/or unnecessary use of liquid coolant to cool thermal components 106 for a respective data processing system may be decreased.

By utilizing compression mechanism with a spring (e.g., torsion spring coupled to the compression mechanism), an actuator to initiate actuation of the compression mechanism may require less power and may require minimal space (e.g., smaller, fewer components) to position the compression mechanism upstream of the thermal components 106 of the respective data processing system and outside of the respective chassis.

Turning to FIG. 2F, a diagram illustrating a side view of a compression mechanism 212 coupled to a portion of a deformable tube 220 in accordance with an embodiment is shown.

The compression mechanism 212 illustrated in FIG. 2F may include a secondary design of a compression mechanism using a scissor mechanism to apply pressure to a portion of the liquid cooling loop (e.g., deformable tube 220). In contrast to that shown in FIGS. 2B-2E, this compression mechanism focuses on the use of a powered motor to actuate gears to extend arms of a scissor mechanism to apply pressure to external sides of a portion liquid cooling loop.

Compression mechanism 212 may include motor 240, arms 244, screw 246, compression structure 248, and/or housing component 242. Motor 240 may include any type of motor (e.g., a direct current or stepper motor) with a motor shaft (e.g., not explicitly shown) coupled to an actuator (e.g., actuator 222) and a gear reduction system (e.g., a worm gear, planetary gear train, etc.) attached to the motor shaft. Motor 240 may be used to convert electrical energy into mechanical rotational motion.

The gear-driven shaft may rotate, for example, a lead screw (e.g., screw 246) which may drive a scissor-like linkage (e.g., arms 244). The scissor-like linkage may follow a principle of a four-bar mechanism, where input motion is amplified to create a large pinching force (e.g., downward pressure) applied to a portion of the liquid cooling loop (e.g., deformable tube 220).

The scissor mechanism shown in FIGS. 2F-2G may utilize a mechanical advantage which increases as the angle between the arms (e.g., arms 244) decreases. For example, when the angle is large, small movements of screw 246 may cause large displacements of the pinched arms 244. However, when the angle (e.g., between arms 244) is small, the movement may be minimal, but the force output (e.g., force applied to the deformable tube 220) may be maximized. Likewise, the output force (e.g., force applied to the deformable tube 220) may depend on the input force from motor 240 and screw 246. Consequently, as the scissor mechanism extends, compression structure 248 may apply a downwards pressure on the deformable tube 220 (e.g., as shown in FIG. 2G), thereby restricting the flow of liquid coolant into the liquid cooling tube.

Similarly to FIGS. 2B-2E, deformable tube 220 may be subjected to an external force (e.g., caused by compression structure 248 as shown in FIG. 2G) and as such, deformable tube 220 may deform to occlude the flow of the liquid coolant to flow through deformable tube 220. For example, as deformable tube 220 is pinched (e.g., application of pressure to at least two external sides of deformable tube 220), a cross sectional area may decrease, increasing fluid velocity and reducing pressure.

For example, the application of pressure (e.g., downward force) to deformable tube 220 may be indicated in FIG. 2G by the shaded arrow that points downward toward the bottom of the house component 242 (e.g., which may encapsulate and/or apply pressure at least one external side of the deformable tube 220).

Compression mechanism 212 may be adapted to reversibly seal a portion of the liquid cooling loop. For example, when motor 2440 rotates in the opposite direction, the scissor mechanism may retract (e.g., the angle between arms 244 may decrease) and may reduce the application of pressure applied to deformable tube 220. For example, an elasticity of deformable tube 220 may allow deformable tube 220 to return to its original shape (e.g., a circular shape), thereby restoring the flow of fluid (e.g. liquid coolant) into the interior of the data processing system. The position of compression mechanism 212 may return to a retracted position as shown in FIG. 2F.

By utilizing the compression mechanism that includes the scissor mechanism, application of pressure on a portion of the liquid cooling loop to deform may be more likely to be controlled and sealing the fluid flow through the portion of the liquid cooling loop may be reversed without physical intervention (e.g., human physically resetting the compression mechanism).

Thus, the vulnerabilities enabled by the connection points between the manifold and the liquid cooling loops to the respective data processing systems may be managed by utilizing a compression mechanism such as compression mechanism 212. For additional information regarding how a compression mechanism such as compression mechanism 212 may be used with a rack system (e.g., 200), refer to FIGS. 2A-2G discussed above.

While illustrated in FIGS. 2A-2G with a limited number of specific components, a system (e.g., a rack system) may include additional, fewer, and/or different components without departing from embodiments disclosed herein.

As discussed above, the components of FIGS. 1-2G may facilitate and/or perform various functionalities to manage a system that may include a rack for housing data processing systems, each data processing system including a heat generating component, a chassis for housing the heat generating component, a liquid cooling loop (e.g., to cool the heat generating component), and a compression mechanism (e.g., adapted to reversibly seal a portion of the liquid cooling loop to prevent coolant from being circulated by the liquid cooling loop into an interior of the data processing system).

Any of the processes and/or components illustrated in and/or discussed with regard to FIGS. 1-2G may be implemented with and/or used in conjunction with one or more computing devices.

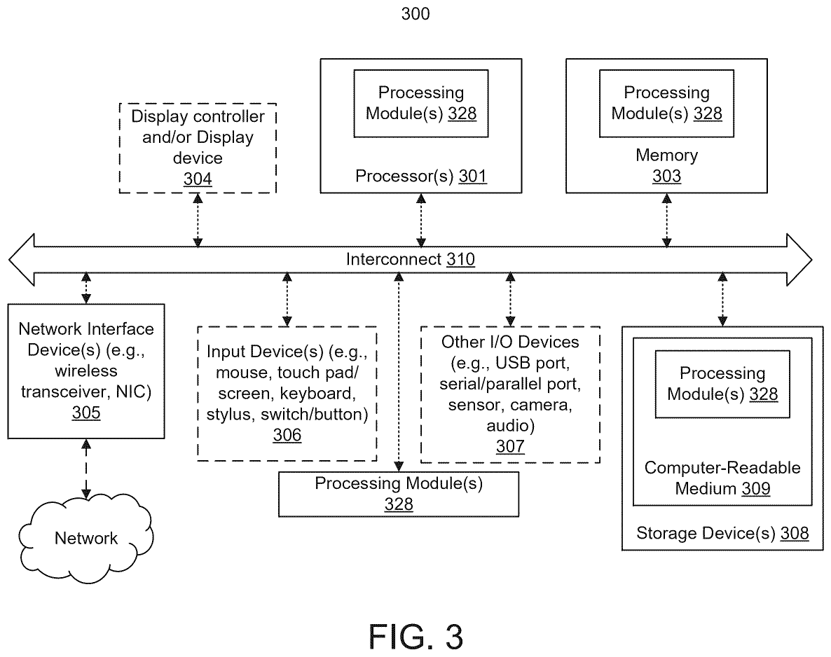

Any of the components illustrated in FIGS. 1-2G may be implemented with one or more computing devices. Turning to FIG. 3, a block diagram illustrating an example of a data processing system (e.g., a computing device) in accordance with an embodiment is shown. For example, system 300 may represent any of data processing systems described above performing any of the processes or methods described above. System 300 can include many different components. These components can be implemented as integrated circuits (ICs), portions thereof, discrete electronic devices, or other modules adapted to a circuit board such as a motherboard or add-in card of the computer system, or as components otherwise incorporated within a chassis of the computer system. Note also that system 300 is intended to show a high level view of many components of the computer system. However, it is to be understood that additional components may be present in certain implementations and furthermore, different arrangement of the components shown may occur in other implementations. System 300 may represent a desktop, a laptop, a tablet, a server, a mobile phone, a media player, a personal digital assistant (PDA), a personal communicator, a gaming device, a network router or hub, a wireless access point (AP) or repeater, a set-top box, or a combination thereof. Further, while only a single machine or system is illustrated, the term “machine” or “system” shall also be taken to include any collection of machines or systems that individually or jointly execute a set (or multiple sets) of instructions to perform any one or more of the methodologies discussed herein.

In one embodiment, system 300 includes processor 301, memory 303, and devices 305-307 via a bus or an interconnect 310. Processor 301 may represent a single processor or multiple processors with a single processor core or multiple processor cores included therein. Processor 301 may represent one or more general-purpose processors such as a microprocessor, a central processing unit (CPU), or the like. More particularly, processor 301 may be a complex instruction set computing (CISC) microprocessor, reduced instruction set computing (RISC) microprocessor, very long instruction word (VLIW) microprocessor, or processor implementing other instruction sets, or processors implementing a combination of instruction sets. Processor 301 may also be one or more special-purpose processors such as an application specific integrated circuit (ASIC), a cellular or baseband processor, a field programmable gate array (FPGA), a digital signal processor (DSP), a network processor, a graphics processor, a network processor, a communications processor, a cryptographic processor, a co-processor, an embedded processor, or any other type of logic capable of processing instructions.

Processor 301, which may be a low power multi-core processor socket such as an ultra-low voltage processor, may act as a main processing unit and central hub for communication with the various components of the system. Such processor can be implemented as a system on chip (SoC). Processor 301 is configured to execute instructions for performing the operations discussed herein. System 300 may further include a graphics interface that communicates with optional graphics subsystem 304, which may include a display controller, a graphics processor, and/or a display device.

Processor 301 may communicate with memory 303, which in one embodiment can be implemented via multiple memory devices to provide for a given amount of system memory. Memory 303 may include one or more volatile storage (or memory) devices such as random access memory (RAM), dynamic RAM (DRAM), synchronous DRAM (SDRAM), static RAM (SRAM), or other types of storage devices. Memory 303 may store information including sequences of instructions that are executed by processor 301, or any other device. For example, executable code and/or data of a variety of operating systems, device drivers, firmware (e.g., input output basic system or BIOS), and/or applications can be loaded in memory 303 and executed by processor 301. An operating system can be any kind of operating systems, such as, for example, Windows® operating system from Microsoft®, Mac OS®/iOS® from Apple, Android® from Google®, Linux®, Unix®, or other real-time or embedded operating systems such as VxWorks.

System 300 may further include IO devices such as devices (e.g., 305, 306, 307, 308) including network interface device(s) 305, optional input device(s) 306, and other optional IO device(s) 307. Network interface device(s) 305 may include a wireless transceiver and/or a network interface card (NIC). The wireless transceiver may be a WiFi transceiver, an infrared transceiver, a Bluetooth transceiver, a WiMax transceiver, a wireless cellular telephony transceiver, a satellite transceiver (e.g., a global positioning system (GPS) transceiver), or other radio frequency (RF) transceivers, or a combination thereof. The NIC may be an Ethernet card.

Input device(s) 306 may include a mouse, a touch pad, a touch sensitive screen (which may be integrated with a display device of optional graphics subsystem 304), a pointer device such as a stylus, and/or a keyboard (e.g., physical keyboard or a virtual keyboard displayed as part of a touch sensitive screen). For example, input device(s) 306 may include a touch screen controller coupled to a touch screen. The touch screen and touch screen controller can, for example, detect contact and movement or break thereof using any of a plurality of touch sensitivity technologies, including but not limited to capacitive, resistive, infrared, and surface acoustic wave technologies, as well as other proximity sensor arrays or other elements for determining one or more points of contact with the touch screen.

IO devices 307 may include an audio device. An audio device may include a speaker and/or a microphone to facilitate voice-enabled functions, such as voice recognition, voice replication, digital recording, and/or telephony functions. Other IO devices 307 may further include universal serial bus (USB) port(s), parallel port(s), serial port(s), a printer, a network interface, a bus bridge (e.g., a PCI-PCI bridge), sensor(s) (e.g., a motion sensor such as an accelerometer, gyroscope, a magnetometer, a light sensor, compass, a proximity sensor, etc.), or a combination thereof. IO device(s) 307 may further include an imaging processing subsystem (e.g., a camera), which may include an optical sensor, such as a charged coupled device (CCD) or a complementary metal-oxide semiconductor (CMOS) optical sensor, utilized to facilitate camera functions, such as recording photographs and video clips. Certain sensors may be coupled to interconnect 310 via a sensor hub (not shown), while other devices such as a keyboard or thermal sensor may be controlled by an embedded controller (not shown), dependent upon the specific configuration or design of system 300.

To provide for persistent storage of information such as data, applications, one or more operating systems and so forth, a mass storage (not shown) may also couple to processor 301. In various embodiments, to enable a thinner and lighter system design as well as to improve system responsiveness, this mass storage may be implemented via a solid state device (SSD). However, in other embodiments, the mass storage may primarily be implemented using a hard disk drive (HDD) with a smaller amount of SSD storage to act as an SSD cache to enable non-volatile storage of context state and other such information during power down events so that a fast power up can occur on re-initiation of system activities. Also a flash device may be coupled to processor 301, e.g., via a serial peripheral interface (SPI). This flash device may provide for non-volatile storage of system software, including a basic input/output software (BIOS) as well as other firmware of the system.

Storage device 308 may include computer-readable storage medium 309 (also known as a machine-readable storage medium or a computer-readable medium) on which is stored one or more sets of instructions or software (e.g., processing module, unit, and/or processing module/unit/logic 328) embodying any one or more of the methodologies or functions described herein. Processing module/unit/logic 328 may represent any of the components described above. Processing module/unit/logic 328 may also reside, completely or at least partially, within memory 303 and/or within processor 301 during execution thereof by system 300, memory 303 and processor 301 also constituting machine-accessible storage media. Processing module/unit/logic 328 may further be transmitted or received over a network via network interface device(s) 305.

Computer-readable storage medium 309 may also be used to store some software functionalities described above persistently. While computer-readable storage medium 309 is shown in an exemplary embodiment to be a single medium, the term “computer-readable storage medium” should be taken to include a single medium or multiple media (e.g., a centralized or distributed database, and/or associated caches and servers) that store the one or more sets of instructions. The terms “computer-readable storage medium” shall also be taken to include any medium that is capable of storing or encoding a set of instructions for execution by the machine and that cause the machine to perform any one or more of the methodologies of embodiments disclosed herein. The term “computer-readable storage medium” shall accordingly be taken to include, but not be limited to, solid-state memories, and optical and magnetic media, or any other non-transitory machine-readable medium.

Processing module/unit/logic 328, components and other features described herein can be implemented as discrete hardware components or integrated in the functionality of hardware components such as ASICS, FPGAs, DSPs or similar devices. In addition, processing module/unit/logic 328 can be implemented as firmware or functional circuitry within hardware devices. Further, processing module/unit/logic 328 can be implemented in any combination hardware devices and software components.

Note that while system 300 is illustrated with various components of a data processing system, it is not intended to represent any particular architecture or manner of interconnecting the components; as such details are not germane to embodiments disclosed herein. It will also be appreciated that network computers, handheld computers, mobile phones, servers, and/or other data processing systems which have fewer components or perhaps more components may also be used with embodiments disclosed herein.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities.

It should be borne in mind, however, that all of these and similar terms are to be associated with the appropriate physical quantities and are merely convenient labels applied to these quantities. Unless specifically stated otherwise as apparent from the above discussion, it is appreciated that throughout the description, discussions utilizing terms such as those set forth in the claims below, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

Embodiments disclosed herein also relate to an apparatus for performing the operations herein. Such a computer program is stored in a non-transitory computer readable medium. A non-transitory machine-readable medium includes any mechanism for storing information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices).

The processes or methods depicted in the preceding figures may be performed by processing logic that comprises hardware (e.g. circuitry, dedicated logic, etc.), software (e.g., embodied on a non-transitory computer readable medium), or a combination of both. Although the processes or methods are described above in terms of some sequential operations, it should be appreciated that some of the operations described may be performed in a different order. Moreover, some operations may be performed in parallel rather than sequentially.

Embodiments disclosed herein are not described with reference to any particular programming language. It will be appreciated that a variety of programming languages may be used to implement the teachings of embodiments disclosed herein.

In the foregoing specification, embodiments have been described with reference to specific exemplary embodiments thereof. It will be evident that various modifications may be made thereto without departing from the broader spirit and scope of the embodiments disclosed herein as set forth in the following claims. The specification and drawings are, accordingly, to be regarded in an illustrative sense rather than a restrictive sense.

What is claimed is:

1. A data processing system, comprising:
a heat generating component;
a liquid cooling loop to cool the heat generating component; and
a compression mechanism adapted to:
reversibly seal a portion of the cooling loop to prevent coolant from being circulated by the liquid cooling loop into an interior of the data processing system, the portion of the cooling loop being sealed by deforming a portion of the liquid cooling loop to seal a fluid flow path through the liquid cooling loop.

2. The data processing system of claim 1, wherein the portion of the liquid cooling loop is deformed through application of pressure to at least two external sides of the portion of the liquid cooling loop.

3. The data processing system of claim 2, wherein the portion of the liquid cooling loop comprises a deformable tube, and the application of the pressure to the at least two external sides causes a cross section to change from being circular in shape to elliptical in shape.

4. The data processing system of claim 1, wherein the compression mechanism comprises:
an actuatable return mechanism adapted to press a surface of the compression mechanism against the portion of the cooling loop to cause the deforming of the portion of the liquid cooling loop.

5. The data processing system of claim 4, wherein the actuatable return mechanism is a return spring.

6. The data processing system of claim 4, wherein the actuatable return mechanism is a powered scissor mechanism.

7. The data processing system of claim 4, wherein the compression mechanism further comprises:
an actuator coupled to the actuatable return mechanism, the actuator being coupled to a control system, and the control system being adapted to actuate the actuator based on conditions present in the data processing system.

8. The data processing system of claim 1, further comprising:
a chassis for housing the heat generating component, wherein the portion of the of the cooling loop is positioned outside of the chassis.

9. The data processing system of claim 8, wherein the liquid cooling loop is at least partially positioned inside of the chassis and at least partially positioned outside of the chassis.

10. The data processing system of claim 9, wherein the portion of the liquid cooling loop is positioned upstream of the heat generating component.

11. A rack system, comprising:
a rack for housing data processing systems; and
a data processing system positioned in the rack, the data processing system comprising:
a heat generating component;
a liquid cooling loop to cool the heat generating component; and
a compression mechanism adapted to:
reversibly seal a portion of the cooling loop to prevent coolant from being circulated by the liquid cooling loop into an interior of the data processing system, the portion of the cooling loop being sealed by deforming a portion of the liquid cooling loop to seal a fluid flow path through the liquid cooling loop.

12. The rack system of claim 11, wherein the portion of the liquid cooling loop is deformed through application of pressure to at least two external sides of the portion of the liquid cooling loop.

13. The rack system of claim 12, the portion of the liquid cooling loop comprises a deformable tube, and the application of the pressure to the at least two external sides causes a cross section to change from being circular in shape to elliptical in shape.

14. The rack system of claim 11, the compression mechanism comprises:
an actuatable return mechanism adapted to press a surface of the compression mechanism against the portion of the cooling loop to cause the deforming of the portion of the liquid cooling loop.

15. The rack system of claim 14, wherein the actuatable return mechanism is a return spring.

16. An enclosure for a data processing system, the enclosure comprising:
a liquid cooling loop to cool a heat generating component positioned in the enclosure; and
a compression mechanism adapted to:
reversibly seal a portion of the cooling loop to prevent coolant from being
circulated by the liquid cooling loop into an interior of the data processing system, the portion of the cooling loop being sealed by deforming a portion of the liquid cooling loop to seal a fluid flow path through the liquid cooling loop.

17. The enclosure of claim 16, wherein the portion of the liquid cooling loop is deformed through application of pressure to at least two external sides of the portion of the liquid cooling loop.

18. The enclosure of claim 17, wherein the portion of the liquid cooling loop comprises a deformable tube, and the application of the pressure to the at least two external sides causes a cross section to change from being circular in shape to elliptical in shape.

19. The enclosure of claim 16, wherein the compression mechanism comprises:
an actuatable return mechanism adapted to press a surface of the compression mechanism against the portion of the cooling loop to cause the deforming of the portion of the liquid cooling loop.

20. The enclosure of claim 19, wherein the actuatable return mechanism is a return spring.
